(19) United States
(12) Patent Application Publication
(10) Pub. No.: US 2016/0190381 A1
(43) Pub. Date: Jun. 30, 2016

(54) PHOTODETECTOR

(71) Applicant: GIANTPLUS TECHNOLOGY CO., LTD., MIAO-LI COUNTY (TW)

(72) Inventor: JUI-CHIN WU, MIAO-LI COUNTY (TW)

(21) Appl. No.: 14/604,876

(22) Filed: Jan. 26, 2015

(30) Foreign Application Priority Data
Dec. 26, 2014 (TW) 103223094

(51) Int. Cl. H01L 31/18; H01L 31/101

(52) U.S. Cl. CPC H01L 31/186; H01L 31/101

(57) ABSTRACT

The present invention provides a photodetector, which comprises a substrate, a gate metal layer, an isolation layer, a transport layer, an insulating layer, an optoelectronic device, and a common metal layer. The gate metal layer is disposed on the substrate; the isolation layer is disposed on the gate metal layer and the substrate; the transport layer is disposed on the isolation layer; the insulating layer is disposed on the transport layer; the optoelectronic device is disposed on the transport layer but not on the gate metal layer; and the common metal layer is disposed on the optoelectronic device. In an etch-back process for removing the common metal layer, the transport layer cannot be removed. Alternatively, in another etch-back process for removing the transport layer, the isolation layer, and the layers and device on the isolation layer, the gate metal layer cannot be removed.

### FIELD OF THE INVENTION

The present invention relates generally to a photodetector, and particularly to a photodetector arranging its structure according to chemical properties.

### BACKGROUND OF THE INVENTION

In the industry, similar alloys are generally adopted as the metal materials for various layers of a photodetector. Thereby, the materials of metal layers are akin to each other. In other words, the etching solutions for the metal layers are similar as well. Nonetheless, reworks might be required when defective phenomena, such as photoresist shift, occur in the fabrication process for forming metal layers. In general, when a metal layer is etched by an etching solution during rework process, the metal layer below it will be etched as well. Hence, an intact metal layer is also etched during rework process. That is to say, when removing a defective metal layer during rework process, the integrity of the other intact metal layers is hard to be maintained.

Accordingly, the present invention provides a photodetector for solving the above problem.

### SUMMARY

An objective of the present invention is to provide a photodetector, which includes the reworkable property for solving defective phenomena in the fabrication process of forming metal layers in a photodetector.

Another objective of the present invention is to provide a photodetector. By arranging the structure according to the chemical properties of each layer, an etching solution can elicit different reaction activities for different layers and thus defective metal layers can be removed sequentially. Accordingly, the problem of maintaining the integrity of the other intact metal layers during removing the defective metal layer in the rework process can be solved.

In order to achieve the objectives described above, the photodetector according to the present invention comprises a substrate, a gate metal layer, an isolation layer, a transport layer, an insulating layer, an optoelectronic device, and a common metal layer. The gate metal layer is disposed on the substrate; the isolation layer is disposed on the gate metal layer and the substrate; the transport layer is disposed on the isolation layer; the insulating layer is disposed on the transport layer; the optoelectronic device is disposed on the transport layer but not on the gate metal layer; and the common metal layer is disposed on the optoelectronic device. In an etch-back process for removing the common metal layer, the transport layer cannot be removed. And/or, in another etch-back process for removing the transport layer, the isolation layer, and the layers and device on the isolation layer, the gate metal layer cannot be removed.

### BRIEF DESCRIPTION OF THE DRAWINGS

FIG. 1 shows atop view of the photodetector according to an embodiment of the present invention; and

FIG. 2 shows a cross-sectional view along the line ZZ′ in FIG. 1.

### DETAILED DESCRIPTION

In order to make the structure and characteristics as well as the effectiveness of the present invention to be further understood and recognized, the detailed description of the present invention is provided as follows along with embodiments and accompanying figures.

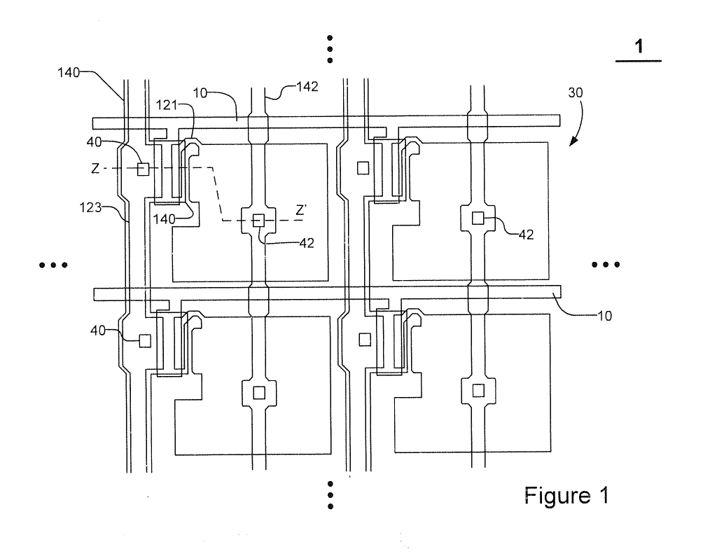

Please refer to FIG. 1, which shows a top view of the photodetector according to an embodiment of the present invention. As shown in the figure, the photodetector 1 according to the present invention comprises a plurality of gate lines 10, a plurality of drain lines 123, a plurality of source lines 121, a plurality of common electrode lines 142, a plurality of contact holes 40, 42, and a plurality of optoelectronic devices 30.

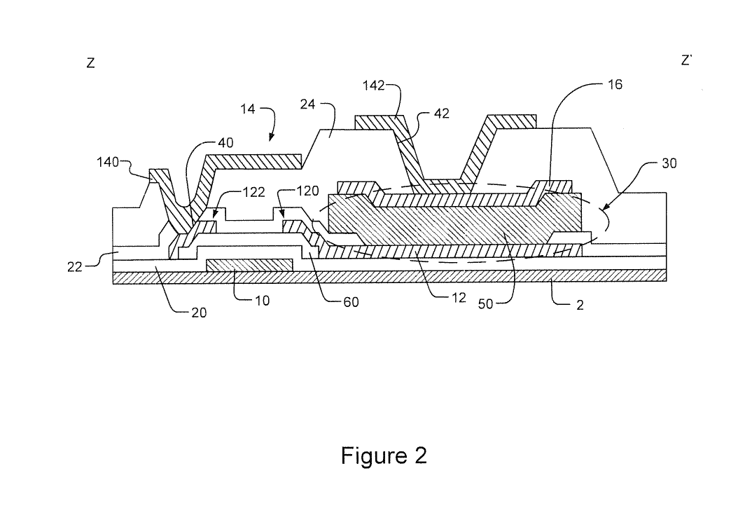

Please refer to FIG. 2, which shows a cross-sectional view along the line ZZ′ in FIG. 1. As shown in the figure, the photodetector 1 according to the present invention comprises a substrate 2, a gate metal layer 10, an isolation layer 20, a semiconductor layer 60, a transport layer 12, an insulating layer 22, an inert layer 24, an optoelectronic device 30, and a common metal layer 14. The gate metal layer 10 is disposed on the substrate 2 and forming the gate line 10; the isolation layer 20 is disposed on the gate metal layer 10 and the substrate 2; the semiconductor layer 60 is stacked on the gate metal layer 10; the transport layer 12 is disposed on the isolation layer 20. Besides, the transport layer 12 is used for forming a drain 122, the drain lines 123 (FIG. 1), a source 120, and the source lines 121 (FIG. 1). The insulating layer 22 is disposed on the transport layer 12; the inert layer 24 is disposed on the insulating layer 22 and the optoelectronic device 30; the optoelectronic device 30 is disposed on the transport layer 12 but not on the gate metal layer 10; and the common metal layer 14 is disposed on the optoelectronic device 30 and used for forming the common electrode lines 142.

A first contact hole 40 of the photodetector 1 penetrates the inert layer 24 and the insulating layer 22 and is formed on the transport layer 12 to exposing the transport layer 12. A second contact hole 42 of the photodetector 1 penetrates the inert layer 24 and is formed on the optoelectronic device 30 to exposing the optoelectronic device 30. The common metal layer 14 contacts the transport layer 12 via the first contact hole 40 and contacts the optoelectronic device 30 via the second contact hole 42. The optoelectronic device 30 according to the present invention comprises a diode layer 50 and a transparent electrode 16. The diode layer 50 is disposed on the insulating layer 22 and the transport layer 12. The transparent electrode 16 is disposed on the diode layer 50.

In addition, the common metal layer 14 of the photodetector 1 is further used for forming repair lines 140, which are parallel with the drain lines 123. The locations of the repair lines 140 correspond to those of the drain lines 123. Besides, the repair lines 140 are connected electrically with the drain lines 123. Thereby, when the drain lines 123 are open-loop, the signal generated by the optoelectronic device 30 can be output via the repair lines 140, enabling the photodetector 1 to operate normally.

Please refer again to FIG. 2. While fabricating the photodetector 1, the chemical properties of the metal layers 10, 12, 14 are arranged. Thus, when one of the metal layer 10, 12, 14 has defects, rework can be performed without influencing the other metal layers. The chemical properties described above can be the chemical inertness or activity of the metal layers 10, 12, 14. Moreover, the chemical inertness and activity of the metal layers 10, 12, 14 are measured with respect to the same etching solution. Thereby, while performing wet etching using a first etching solution, such as aluminum etchant, the chemical inertness of the common metal layer 14 is lower than that of the transport layer 12 and the chemical inertness of the transport layer 12 is lower than that of the gate metal layer 10. Consequently, while performing rework using the first etching solution, the etching effectiveness of the common metal layer 14 is better than that of the transport layer 12 and the etching effectiveness of the transport layer 12 is better than that of the gate metal layer 10. In other words, in an etch-back process for removing the common metal layer 14, the transport layer 12 will not be removed. Alternatively, while removing the transport layer 12 using the first etching solution, the gate metal layer 10 will not be removed. Thereby, the photodetector according to the present invention has a structure arranged according to chemical properties.

For example, the metal material of the common metal layer 14 according to the present invention is copper (Cu) or its alloy; the metal material of the transport layer 12 is molybdenum (Mo) or its alloy; and the metal material of the gate metal layer 10 is chrome (Cr) or its alloy. Thereby, when the common metal layer 14 has defects during process, the aluminum etchant can be used for back-etching and removing the common metal layer 14. The etching activity for the common metal layer 14 is higher than that for the transport layer 12. Hence, when the aluminum etchant removes the common metal layer 14, the transport layer 12 will not be removed. Likewise, when the transport layer 12 has defects during process, the aluminum etchant can be used for back-etching and removing the transport layer 12. The etching activity for the transport layer 12 is higher than that for the gate metal layer 10. Hence, when the aluminum etchant removes the transport layer 12, the gate metal layer 10 will not be removed. Accordingly, the metal layers 10, 12, 14 according to the present invention are arranged according to the chemical properties so that reworks can be done on the defective metal layer only but not influencing the other ones.

In another example, the metal material of the common metal layer 14 is copper (Cu) or its alloy; the metal material of the transport layer 12 is aluminum (Al) or its alloy; and the metal material of the gate metal layer 10 is chrome (Cr) or its alloy. In addition, different metal materials correspond to different etching solutions. For example, a second etching solution for copper is hydrogen peroxide (H₂O₂); a third etching solution for aluminum is aluminum etchant; and a fourth etching solution for chrome is ceric ammonium nitrate. Thereby, when the etching solution is hydrogen peroxide, the chemical inertness of the common metal layer 14 is lower than that of the transport layer 12; when the etching solution is aluminum etchant, the chemical inertness of the transport layer 12 is lower than that of the gate metal layer 10. Thus, when the copper common metal layer 14 has defects during process, hydrogen peroxide can be used in rework process for removing the common metal layer 14. Nonetheless, hydrogen peroxide cannot remove the aluminum transport layer 12. That is to say, in the etch-back process for removing the common metal layer 14, the transport layer 12 will not be removed.

Alternatively, when the aluminum transport layer 12 has defects during process, aluminum etchant can be used in rework process for removing the transport layer 12. Nonetheless, aluminum etchant cannot remove the chrome gate metal layer 10. That is to say, in another etch-back process for removing the transport layer 12 and after removing the isolation layer 20 as well as the layers and device on the isolation layer 20, the gate metal layer 10 will not be removed. Please refer again to FIG. 2. The above arrangement can be also applied between the common metal layer 14 and the transparent electrode 16. Then the chemical inertness of the etching solution for the common metal layer 14 is lower than that for the transparent electrode 16. In other words, in the etch-back process for removing the common metal layer 14, the transparent electrode 16 will not be removed. Furthermore, etching can be divided into wet etching and dry etching. The present invention can be applied to dry etching as well.

To sum up, the present invention provides a photodetector arranged according to chemical properties. The photodetector comprises a substrate, a gate metal layer, an isolation layer, a transport layer, an insulating layer, an optoelectronic device, and a common metal layer. The gate metal layer is disposed on the substrate; the isolation layer is disposed on the gate metal layer and the substrate; the transport layer is disposed on the isolation layer; the insulating layer is disposed on the transport layer; the optoelectronic device is disposed on the transport layer but not on the gate metal layer; and the common metal layer is disposed on the optoelectronic device. In an etch-back process for removing the common metal layer, the transport layer cannot be removed. And/or, in another etch-back process for removing the transport layer, the isolation layer, and the layers and device on the isolation layer, the gate metal layer cannot be removed.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A photodetector, comprising:
a substrate;
a gate metal layer, disposed on said substrate;
an isolation layer, disposed on said gate metal layer and said substrate;
a transport layer, disposed on said isolation layer;
an insulating layer, disposed on said transport layer;
an optoelectronic device, disposed on said transport layer but not on said gate metal layer; and
a common metal layer, disposed on said optoelectronic device;
wherein the chemical inertness of said common metal layer is lower than the chemical inertness of said transport layer, the chemical inertness of said transport layer is lower than the chemical inertness of said gate metal layer.

2. The photodetector of claim 1, wherein the chemical inertness of said common metal layer correspond to a first etching solution is lower than the chemical inertness of said transport layer correspond to said first etching solution; the chemical inertness of said transport layer correspond to a second etching solution is lower than the chemical inertness of said gate metal layer correspond to said second etching solution.

3. The photodetector of claim 1, wherein said transport layer forms a drain and a source.

4. The photodetector of claim 1, and further comprising an inert layer, disposed on said insulating layer and said optoelectronic device.

5. The photodetector of claim 1, and further comprising a semiconductor layer, stacked between said isolation layer and said transport layer, and disposed on said gate metal layer.

6. The photodetector of claim 4, and further comprising:
a first contact hole, penetrating said inert layer and said insulating layer, and formed on said transport layer for exposing said transport layer; and
a second contact hole, penetrating said inert layer, and formed on said optoelectronic device for exposing said optoelectronic device.

7. The photodetector of claim 6, wherein said common metal layer contacts said transport layer via said first contact hole, and said common metal layer contacts said optoelectronic device via said second contact hole.

8. The photodetector of claim 1, and wherein said optoelectronic device comprising:
a diode layer, disposed on said insulating layer and said transport layer; and
a transparent electrode, disposed on said diode layer;
wherein said common metal layer is disposed on said transparent electrode.

9. The photodetector of claim 8, wherein the chemical inertness of said common metal layer correspond to an etching solution is lower than the chemical inertness of said transparent electrode correspond to said etching solution.
